(19) United States
(12) Patent Application Publication
(10) Pub. No.: US 2006/0192223 A1
(43) Pub. Date: Aug. 31, 2006

(54) Nitride semiconductor light emitting device

(75) Inventors: Sung Jun Lee, Seoul (KR); Woong Lin Hwang, Gunpo (KR); Seog Moon Choi, Seoul (KR); Ho Joon Park, Seoul (KR); Sang Hyun Choi, Seoul (KR); Chang Hyun Lim, Seoul (KR)

Correspondence Address: VOLPE AND KOENIG, P.C., UNITED PLAZA, SUITE 1600, 30 SOUTH 17TH STREET, PHILADELPHIA, PA, 19103, US

(73) Assignee: Samsung Electro-Mechanics Co., Ltd., Suwon (KR)

(21) Appl. No.: 11/313,515

(22) Filed: Dec. 21, 2005

(30) Foreign Application Priority Data
Feb. 28, 2005 (KR) 10-2005-0016522

(51) Int. Cl. H01L 33/00

(52) U.S. Cl. 257/99

(57) ABSTRACT

The invention relates to a flip-chip nitride semiconductor LED. In the LED, a light emitting structure has first and second conductivity type nitride semiconductor layers and an active layer interposed therebetween. Each of plurality of first and second electrodes has a bonding pad placed adjacent to a top corner of the light emitting structure and at least one electrode finger extended from the bonding pad. The first and second electrodes are connected to the first and second conductivity type nitride semiconductor layers, respectively. Also, bonding pads are arranged alternately along edges of the light emitting structure with different polarity, in a substantially symmetric configuration with respect to the center of the light emitting structure. In addition, each of electrode fingers is extended from a corresponding pad and bent at least once toward the center of the light emitting structure to adjoin the electrode finger having different polarity.

### CLAIM OF PRIORITY

This application claims the benefit of Korean Patent Application No. 2005-16522 filed on Feb. 28, 2005, in the Korean Intellectual Property Office, the disclosure of which is incorporated herein by reference.

### BACKGROUND OF THE INVENTION

1. Field of the Invention

The present invention relates to a nitride semiconductor Light Emitting Device (LED). More particularly, the present invention relates to a high-efficiency large-sized nitride semiconductor LED to be adequately used for high-power lighting equipment.

2. Description of the Related Art

In general, a nitride semiconductor is made of group III-V semiconductor crystal such as GaN, InN, and AlN, and is widely used for a Light Emitting Device (LED) capable of producing short-wave light such as ultraviolet ray and green light, and especially blue light. This nitride semiconductor LED is manufactured by using an insulating substrate such as a sapphire substrate or a SiC substrate that satisfies lattice matching conditions for crystalline growth. As a result, typically, the nitride semiconductor LED has a planar structure in which two electrodes coupled to n-type and p-type nitride semiconductor layers are arranged to face one direction on a surface of a light emitting structure.

Compared to a vertical LED in which two electrodes are arranged on opposed faces, a planar nitride LED has a small effective light emitting area due to uneven distribution of current on a total light emitting area. Also, the planar nitride LED has low light emitting efficiency per light emitting area. The planar LED and limited light emitting efficiency thereof will be explained in reference to FIGS. 1a and 1b.

FIGS. 1a and 1b illustrate a type of a conventional nitride semiconductor LED 10.

In the nitride semiconductor LED 10, as shown in FIG. 1a, an n-electrode 18 and a p-electrode 19 are arranged to face upward, along a diagonal line on a substantially square surface.

More specifically, referring to FIG. 1b showing a sectional view taken along the line A-A′ of FIG. 1a, the nitride semiconductor LED 10 includes an n-type nitride semiconductor layer 12, an active layer 13 and a p-type nitride semiconductor layer 14 sequentially formed on a sapphire substrate 11. The p-type nitride semiconductor layer 14 may have a transparent electrode layer 17 such as ITO to allow current spreading effect across the total area.

As explained earlier, the sapphire substrate 11 used to form the nitride semiconductor layer is electrically insulating, and thus the n-electrode 18 is connected to the n-type nitride semiconductor layer 12 to be formed on an area where the p-type nitride semiconductor layer 14 and the active layer 13 are partially removed.

In a planar semiconductor LED 10 shown in FIGS. 1a and 1b, current flow between the two electrodes is concentrated on a narrow path, thus increasing operating voltage and also reducing a substantial light-emitting area. The nitride semiconductor LED exhibits low current density per unit area owing to its planar structure, and also has low area efficiency resulting from the small light emitting area. Such disadvantages are more manifested in a large-sized LED (e.g. 1000 μm×1000 μm) for lighting device.

Conventionally, to solve this problem, a variety of shapes and arrangements of the p-electrode and n-electrode were suggested to enhance current density and area efficiency. For example, U.S. Pat. No. 6,486,499 (published on Nov. 26, 2002) discloses a method for expanding an effective light emitting area via electrode finger structure.

FIG. 2 shows a surface of the LED having an n-type semiconductor layer 22, an active layer and a p-type semiconductor layer (not shown) sequentially formed on a substrate. On the surface of the LED, an opaque electrode 27 is formed to be connected to the p-type nitride semiconductor layer, and an n-electrode 28 is formed to be connected to the n-type nitride semiconductor layer 22. The opaque electrode 27 has a plurality of p-bonding pads 29 arranged thereon. The n-electrode 28 includes two bonding pads 28a and a plurality of electrode fingers 28b extended therefrom. This electrode structure provides additional current path through the electrode fingers 28b, thus reducing average distance between the electrodes.

The aforesaid conventional type has a plurality of bonding pads arranged complexly to ensure stable flip-chip bonding and uniform current supply. This complicates a bonding process and renders it difficult to support the LED stably. For example, a flip-chip process of the p-bonding pad close to a center is difficult, and asymmetrical arrangement of electrodes on the total area requires too great a number of bonding pads to support the LED stably.

### SUMMARY OF THE INVENTION

The present invention has been made to solve the foregoing problems of the prior art and it is therefore an object of the present invention to provide a flip-chip nitride semiconductor Light Emitting Device (LED) having a new electrode structure capable of arranging bonding pads to ensure easy flip chip bonding process and stable support of the LED, and also enhancing current spreading efficiency.

According to an aspect of the invention for realizing the object, there is provided a nitride semiconductor light emitting device comprising: a light emitting structure having first and second conductivity-type nitride semiconductor layers and an active layer interposed therebetween; and a plurality of first and second electrodes each having a bonding pad placed adjacent to a top corner of the light emitting structure and at least one electrode finger extended from the bonding pad, the first electrodes connected to the first conductivity type nitride semiconductor layer, and the second electrodes connected to the second conductivity type nitride semiconductor layer, wherein bonding pads are arranged alternately along edges of the light emitting structure with different polarity, in a substantially symmetric configuration with respect to the center of the light emitting structure, and wherein each of the electrode fingers is extended from a corresponding pad and bent at least once toward the center of the light emitting structure to adjoin the electrode finger having different polarity.

According to one embodiment of the invention, the light emitting structure is cuboid, and the first electrode bonding pads are placed diagonally on two corners, and the second electrode bonding pads are placed diagonally on the other two corners.

Preferably, to distribute current uniformly, the first and second electrode fingers are almost equally spaced apart from adjacent one of the electrode fingers having different polarity. One pair of the electrode fingers having the same polarity may be connected to each other.

To improve current spreading effect, each of the first and second electrode fingers may comprise a portion extended along a top edge of the light emitting structure toward adjacent one of the bonding pads having different polarity.

Preferably, to boost light emitting efficiency in a flip-chip bonding, the nitride semiconductor LED may further comprise a reflexive ohmic contact layer on the second conductivity-type nitride semiconductor layer to reduce contact resistance, wherein the second electrodes are formed on the reflexive ohmic contact layer.

### BRIEF DESCRIPTION OF THE DRAWINGS

The above and other objects, features and other advantages of the present invention will be more clearly understood from the following detailed description taken in conjunction with the accompanying drawings, in which:

FIG. 1a is a top view of a nitride semiconductor LED of the prior art;

FIG. 1b is a side sectional view of the nitride semiconductor LED shown in FIG. 1a;

FIG. 2 is a top view illustrating another nitride semiconductor LED of the prior art;

FIG. 3a is a top view of a nitride semiconductor LED according to an embodiment of the invention;

FIG. 3b is a side sectional view of the nitride semiconductor LED shown in FIG. 3a;

FIG. 4a is a top view of a nitride semiconductor LED according to other embodiment of the invention;

FIG. 4b is a side sectional view of the nitride semiconductor LED shown in FIG. 4b;

FIG. 5 illustrates a flip-chip LED package including a nitride semiconductor LED according to further another embodiment of the invention.

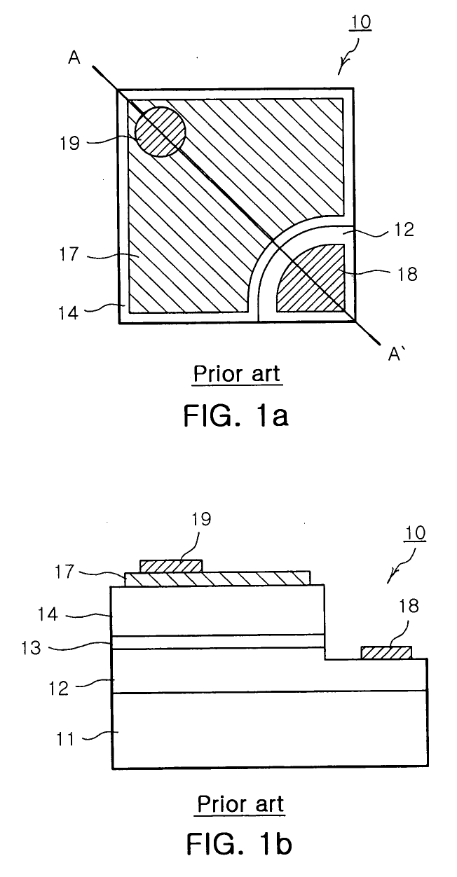

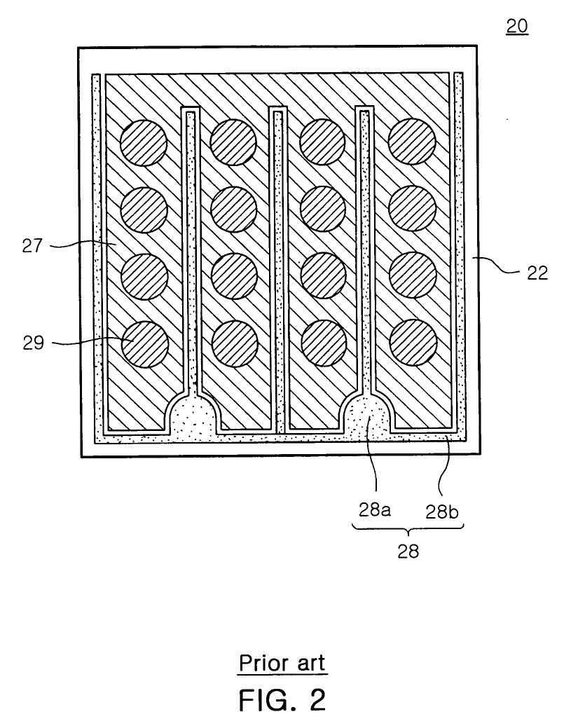

### DETAILED DESCRIPTION OF THE PREFERRED EMBODIMENT

Preferred embodiments of the present invention will now be described in detail with reference to the accompanying drawings.

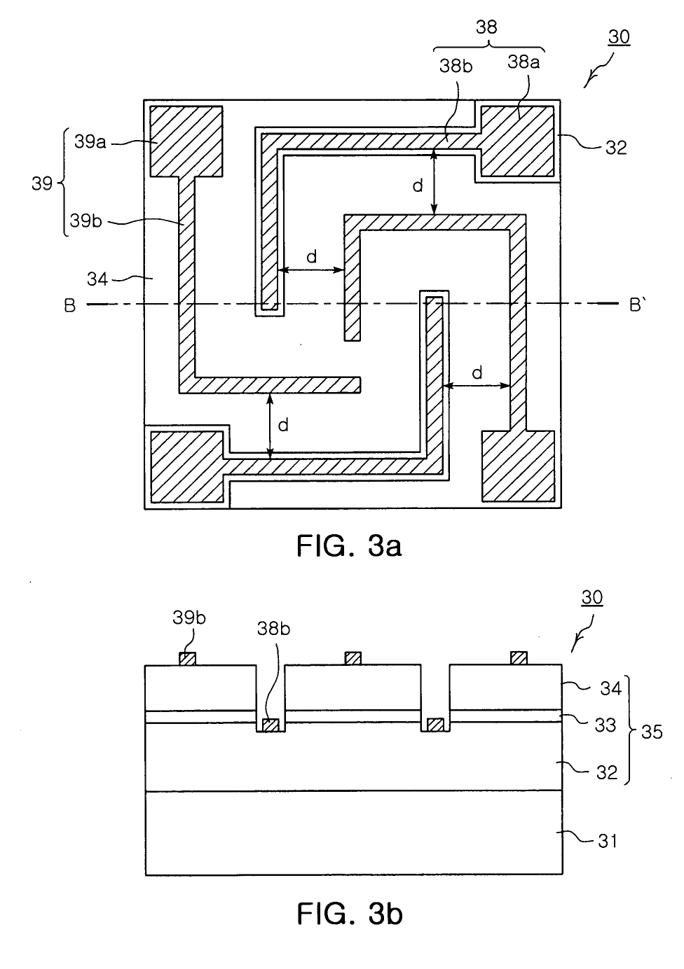

FIG. 3a is a top view of a nitride semiconductor LED according to an embodiment of the invention, and FIG. 3b is a side sectional view taken along the line B-B′ of FIG. 3a.

The nitride semiconductor LED 30 according to this embodiment includes a nitride light emitting structure 35 formed on a substrate 31. The light emitting structure 35 includes a light emitting structure having n-type and p-type nitride semiconductor layers 32,34 and an active layer interposed therebetween (refer to FIG. 3b).

As shown in FIG. 3a, two n-electrodes 38 are formed on the n-type nitride semiconductor layer 32 and two p-electrodes 39 are formed on the p-type nitride semiconductor layer 34. The n- and p-electrodes 38,39 have bonding pads 38a,39a, and electrode fingers (38b,39b) extended thereform. The bonding pads 38a,39a are placed adjacent to a top corner of the light emitting structure. The n- and p-bonding pads 38a,39a are arranged alternately along edges of the light emitting structure with different polarity, in a substantially symmetric configuration with respect to the center of the light emitting structure. More specifically, on the top surface of the cuboid light emitting structure 35, the n-bonding pads 38a are placed diagonally on two corners, and the p-bonding pads 39a are placed diagonally on the other two corners. Such arrangement of the bonding pads 38a,39a ensures stable flip chip bonding as a whole and results in uniform current spreading.

To enhance current spreading effect, each of the electrode fingers 38b, 39b is extended from a corresponding pad 39b, 38b and bent at least once toward the center of the light emitting structure to adjoin the electrode finger having different polarity. As in the embodiment, the electrode fingers 38b,39b may be extended almost spirally toward the center so that the electrode fingers 38b,39b are equally spaced apart from adjacent one of the electrode fingers having different polarity to distribute current uniformly to the total area. Owing to this structure and arrangement of the electrode fingers 38b,39b, electric current supplied from the bonding pads 38a,39a placed on corners is evenly spread across the internal area, expanding the effective light emitting area and resulting in uniform light emitting efficiency in the total area.

The n-electrode 38, as shown in FIG. 3b, is formed on a groove where a p-type nitride semiconductor layer 34 and an active layer 33 are partially removed, and connected to the n-type conductivity type nitride layer 32. In this fashion, the spiral n-electrode finger 38b is placed on a groove structure formed in a configuration corresponding to the arrangement of the n-electrode finger 38b.

The embodiment described above is limited to the light emitting structure having the square surface, and the electrodes having two n- and p-bonding pads formed at corners thereof respectively. But the light emitting structure surface may be hexagon or octagon, and accordingly at least two bonding pads may be formed on areas adjacent to corners.

Also, in the embodiment shown in FIG. 3a, to increase an effective light emitting area, more electrode fingers may be extended from each bonding pad in necessary areas.

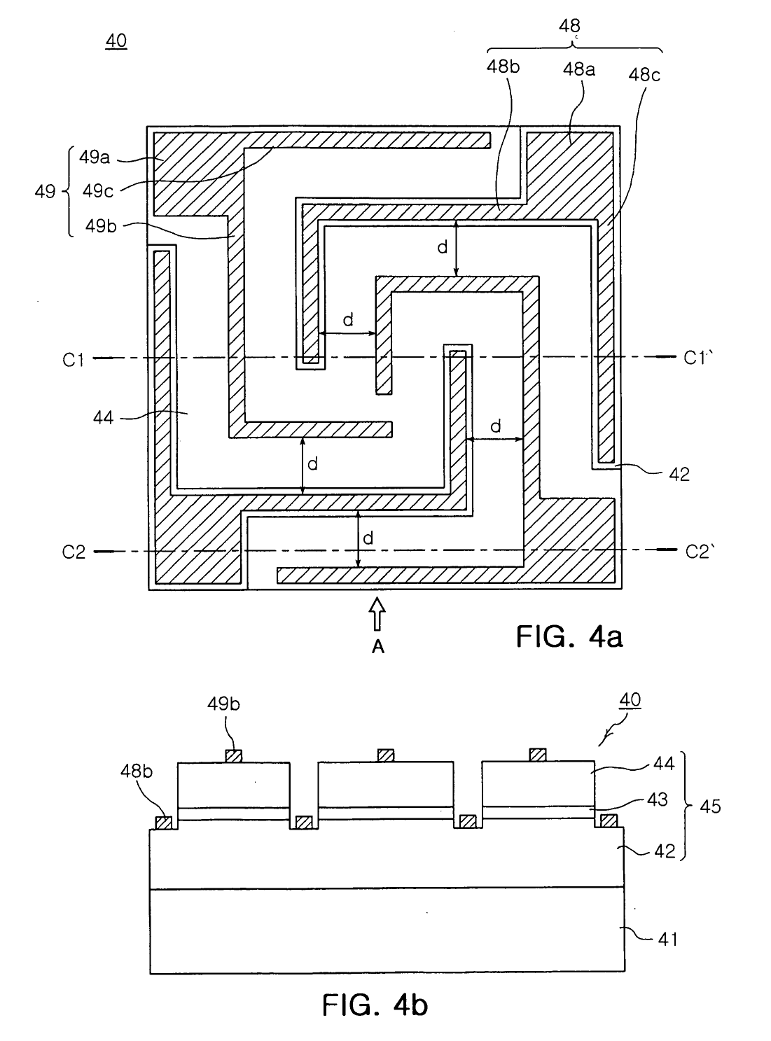

FIGS. 4a and 4b show a nitride semiconductor LED, in which an electrode has a first electrode finger extended and bent toward the center and a second electrode finger extended along an edge.

In a manner similar to FIG. 3b, the nitride semiconductor LED 40 according to this embodiment includes a nitride light emitting structure 45 formed on a substrate 41, and the light emitting structure 45 includes n- and p-type nitride semiconductor layers 42,44 and an active layer 43 interposed therebetween (refer to FIG. 4b).

As shown in FIG. 4a, two n-electrodes 48 are formed on the n-type nitride semiconductor layer 42 and two p-electrodes 49 are formed on the p-type nitride semiconductor layer 44. The n- and p-electrodes 48,49 include bonding pads 48a,49a and first and second electrode fingers 48b,48c,49b,49c extended therefrom. The bonding pads are placed adjacent to top corners of the light emitting structure. In this embodiment, the first electrode fingers 48b or 49b having the same polarity may be connected to each other.

The n- and p-bonding pads 48a,49a are placed at corners on the square surface of the light emitting structure, with same polarity pads diagonally opposed to each other. This allows easy flip chip process and stable support of the LED. Since the bonding pads 48a,49b are arranged alternately along edges of the light emitting structure with different polarity, electric current can be spread uniformly.

In a manner similar to the aforesaid embodiment, to enhance light emitting efficiency in an internal area, the n-electrode 48 and p-electrode 49 are extended spirally toward the center of the light emitting structure, and has the first electrode fingers 48b,49b equally spaced apart from adjacent one of the electrode fingers having different polarity. The n- and p-electrodes 48,49 according to the embodiment has second electrode fingers 48c,49c extended along edges toward adjacent one of the electrode fingers having different polarity. Preferably, the second electrode finger may be placed at equal distance d from adjacent one of the electrode fingers having different polarity. In the electrode arrangement of the embodiment, the second electrode finger 48c or 49c is placed adjacent to the first electrode finger 49b or 48b having different polarity. The second electrode finger 38 employed in the embodiment can increase light emitting efficiency in edges where current can be hardly supplied. Likewise, an electrode finger extended from the bonding pads 48a,49a may be provided to not only edges but also areas where current can be hardly supplied due to their geometrical structure. In the embodiment, the second electrode finger 48c,49c is illustrated in a straight line, but may be bent in accordance with shape and area of the light emitting structure surface.

FIG. 4b is a sectional view of a nitride semiconductor LED taken along the line C1-C1′ of FIG. 4a. Referring to FIG. 4b, when compared with FIG. 3b, the second electrode finger 48c,49c may supply current more uniformly by further subdividing the total area.

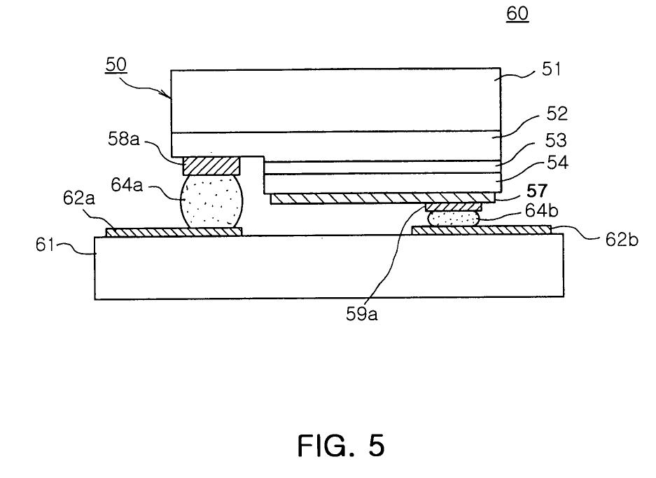

FIG. 5 shows a flip-chip LED package including a nitride semiconductor LED 50 according to further another embodiment of the invention.

FIG. 5 illustrates the flip chip LED package 60 including a package substrate 61 and the nitride semiconductor LED 50 formed thereon. The nitride semiconductor LED 50 includes a sapphire substrate 51, and n-type and p-type nitride semiconductor layers 52,54 formed thereon and an active layer 53 interposed therebetween. The nitride semiconductor LED 50 of FIG. 5 has an electrode structure similar to that of FIG. 4a, with its cross-section taken along the line C2-C2′ and seen in the direction of arrow A shown in FIG. 4a.

However, the flip chip bonding structure further includes a reflexive ohmic electrode 57 formed on the p-type nitride semiconductor layer 52 to increase light quantity toward light output direction, or toward the sapphire substrate 51. The p-electrode 59 is formed on the ohmic electrode 57.

The bonding pads 58a,59a of the nitride semiconductor LED 50 are soldered 64a,64b to conductor patterns 62a,62b of the package substrate 61. The nitride semiconductor LED 50 according to the invention, as illustrated in FIGS. 3b and 4b, has 4 bonding pads 58a,59a (2 are not illustrated) placed adjacent to each corner in a substantially symmetric configuration. Thus, this allows easy flip-chip bonding process and more stable support of the LED 50, attaining mechanical reliability additionally.

As set forth above, new electrode arrangement of the invention enhances current spreading efficiency to increase light emitting efficiency, and ensures easy flip-chip bonding process and stable support of the LED in the flip-chip bonding structure.

While the present invention has been shown and described in connection with the preferred embodiments, it will be apparent to those skilled in the art that modifications and variations can be made without departing from the spirit and scope of the invention as defined by the appended claims.

1. A nitride semiconductor Light Emitting Device (LED) comprising:
a light emitting structure having first and second conductivity-type nitride semiconductor layers and an active layer interposed therebetween; and
a plurality of first and second electrodes each having a bonding pad placed adjacent to a top corner of the light emitting structure and at least one electrode finger extended from the bonding pad, the first electrodes connected to the first conductivity type nitride semiconductor layer, and the second electrodes connected to the second conductivity type nitride semiconductor layer,
wherein bonding pads are arranged alternately along edges of the light emitting structure with different polarity, in a substantially symmetric configuration with respect to the center of the light emitting structure, and
wherein each of the electrode fingers is extended from a corresponding pad and bent at least once toward the center of the light emitting structure to adjoin the electrode finger having different polarity.

2. The nitride semiconductor LED according to claim 1, wherein the light emitting structure is cuboid, and
wherein the first electrode bonding pads are placed diagonally on two corners, and the second electrode bonding pads are placed diagonally on the other two corners.

3. The nitride semiconductor LED according to claim 1, wherein the first and second electrode fingers are almost equally spaced apart from adjacent one of the electrode fingers having different polarity.

4. The nitride semiconductor LED according to claim 1, wherein one pair of the electrode fingers having the same polarity are connected to each other.

5. The nitride semiconductor LED according to claim 1, wherein each of the first and second electrode fingers comprises a portion extended along a top edge of the light emitting structure toward adjacent one of the bonding pads having different polarity.

6. The nitride semiconductor LED according to claim 1, further comprising a reflexive ohmic contact layer on the second conductivity-type nitride semiconductor layer to reduce contact resistance, wherein the second electrodes are formed on the reflexive ohmic contact layer.

7. The nitride semiconductor LED according to claim 2, wherein the first and second electrode fingers are almost equally spaced apart from adjacent one of the electrode fingers having different polarity.

8. The nitride semiconductor LED according to claim 2, wherein one pair of the electrode fingers having the same polarity are connected to each other.
